(19) United States
(12) Patent Application Publication
(10) Pub. No.: US 2003/0102779 A1
(43) Pub. Date: Jun. 5, 2003

(54) Piezoelectric transformer

(75) Inventors: Jong Sun Kim, Kyungki-do (KR); Jin Woo Park, Kyungki-do (KR)

Correspondence Address: LOWE HAUPTMAN GOPSTEIN GILMAN & BERNER, LLP, Suite 310, 1700 Diagonal Road, Alexandria, VA, 22314, US

(73) Assignee: Samsung Electro-Mechanics Co., Ltd.

(21) Appl. No.: 10/040,360

(22) Filed: Jan. 9, 2002

(30) Foreign Application Priority Data
Dec. 5, 2001 (KR) 2001-76433

(51) Int. Cl. H01L 41/04

(52) U.S. Cl. 310/359; 310/365

(57) ABSTRACT

Disclosed is a piezoelectric transformer capable of easily achieving external electrical connection and polarization of electrodes while obtaining stable output characteristics. The piezoelectric transformer includes a piezoelectric member having two opposite rectangular major surfaces as first and second surfaces, and four side surfaces connecting the first and second surfaces. The piezoelectric member is longitudinally divided into two portions to have a first portion and a second portion, thereby longitudinally dividing each of the first and second surfaces into a first surface portion and a second surface portion. The piezoelectric transformer also includes an input electrode formed on the first surface portion of the first surface of the piezoelectric member, a ground electrode formed on the first surface portion of the second surface of the piezoelectric member while being vertically symmetrical with the input electrode, and an output electrode formed on the second portion of the piezoelectric member at an end of the second portion spaced away from the input electrode.

### BACKGROUND OF THE INVENTION

1. Field of the Invention

The present invention relates to a piezoelectric transformer having an improved output electrode structure capable of easily achieving external electrical connection and polarization of electrodes while obtaining improved piezoelectric characteristics.

2. Description of the Related Art

Recently, piezoelectric transformers, which are adapted as high-voltage DC generating devices, have been used at an increased rate, as compared to coil transformers, because they have favorable features of reduced size, high efficiency, high electrical insulation, and nonflammability, as compared to those coil transformers.

Piezoelectric transformers are mainly used in high-voltage power supply devices equipped in inverters for back light adapted to turn on and off color liquid crystal displays of notebooks, PDA (Personal Digital Assistant), DVC (Digital Video Camera), DSC (Digital Still Camera) and the like, static brushes, air cleaners, and ozone generators.

Such a piezoelectric transformer basically consists of a piezoelectric member, and input and output electrodes attached to the piezoelectric member. When AC voltage having a frequency corresponding to the intrinsic vibration frequency of the piezoelectric member is applied to the piezoelectric member via the input electrode, the piezoelectric member vibrates mechanically. The mechanical vibration energy of the piezoelectric member is transformed into electrical energy, and then outputted via the output electrode. Thus, the piezoelectric transformer boosts the input voltage using piezoelectric vibrations.

FIG. 1 illustrates a general Rozen type piezoelectric transformer. As shown in FIG. 1, the Rozen type piezoelectric transformer, which is denoted by the reference numeral 10, includes a piezoelectric member 11 having two opposite rectangular major surfaces, that is, first and second surfaces, and four side surfaces, that is, third through sixth surfaces, connecting the first and second surfaces. The piezoelectric member 11 is longitudinally divided into two portions, that is, a first portion and a second portion. Accordingly, each of the first and second surfaces of the piezoelectric member 11 is longitudinally divided into two surface portions, that is, a first surface portion and a second surface portion. The piezoelectric transformer 10 also includes an input electrode 12 formed on the first surface portion of the first surface of the piezoelectric member 11, an output electrode 13 formed on the third surface of the piezoelectric member 11 not contacting the input electrode 12, and a ground electrode 14 formed on a first surface portion of the second surface of the piezoelectric member 11 while being arranged opposite to the input electrode 12.

When AC voltage of a certain level from an AC power source S is applied between the input electrode 12 and the ground electrode 14 in the above mentioned conventional Rozen type piezoelectric transformer, mechanical vibrations are generated in vertical directions at the first portion of the piezoelectric member 11, that is, a first electrode section, in accordance with the electrical energy of the applied voltage. By virtue of the vibrations, the second portion of the piezoelectric member 11, that is, a second electrode section, vibrates in longitudinal directions. The longitudinal vibrations are transformed into electrical energy which is, in turn, outputted via the output electrode 13. Such a piezoelectric effect provided in accordance with the application of AC voltage serves to generate a boosting effect.

The waveform diagram shown in the lower portion of FIG. 1 illustrates the waveform of vibrations generated at the Rozen type piezoelectric transformer 10.

The first electrode section formed with the input electrode 12 serves as a driving section (or an input section) for transforming electrical energy into mechanical vibration energy, whereas the second electrode section formed with the output electrode 13 serves as an electrical output generating section (or an output section) for transforming vibration energy into electrical energy.

However, the conventional Rozen type piezoelectric transformer 10 has problems in that it is impossible to easily achieve external electrical connection and polarization of the output electrode 13 because the output electrode 13 is arranged at the side surface having a small width and a small area. Furthermore, the output electrode 13 may be damaged when it is polarized.

In order to improve the electrode structure of the above mentioned Rozen type piezoelectric transformer, various structures have been proposed. FIG. 2 illustrates an improved Rozen type piezoelectric transformer.

As shown in FIG. 2, this piezoelectric transformer, which is denoted by the reference numeral 20, includes a rectangular piezoelectric member 21 having the same structure as the piezoelectric member 11 of the Rozen type piezoelectric transformer 10 shown in FIG. 1. Similarly to the Rozen type piezoelectric transformer 10, the piezoelectric transformer 20 also includes an input electrode 22 formed on the first surface portion of the first surface of the piezoelectric member 21, a strip-shaped output electrode 23 formed on the second surface portion of the first surface of the piezoelectric member 21 at the end of the second surface portion spaced away from the input electrode 22, and ground electrodes 24 and 25 respectively formed on the second surface of the piezoelectric member 21 while being vertically symmetrical with the input and output electrodes 22 and 23.

The Rozen type piezoelectric transformer 20 has advantages in that it is possible to easily form desired electrode patterns while easily achieving external electrical connection and polarization of the output electrode 23 because the output electrode 23 is formed at the first surface of the piezoelectric member 21, as the input electrode 21. However, the electrical output generating section (the second electrode section) is insufficiently polarized in a longitudinal direction. Also, there is a problem in that the piezoelectric member exhibits a characteristic dispersion.

### SUMMARY OF THE INVENTION

Therefore, the present invention has been made in view of the above mentioned problems involved with the related art, and an object of the invention is to provide a piezoelectric transformer capable of easily achieving external electrical connection and polarization of electrodes while obtaining stable output characteristics.

Another object of the invention is to provide a piezoelectric transformer capable of adjusting the length of an output electrode thereof, thereby achieving an adjustment of output capacitance.

In accordance with one aspect, the present invention provides a piezoelectric transformer comprising:

a piezoelectric member having two opposite rectangular major surfaces as first and second surfaces, and four side surfaces connecting the first and second surfaces, the piezoelectric member being longitudinally divided into two portions to have a first portion and a second portion, thereby longitudinally dividing each of the first and second surfaces into a first surface portion and a second surface portion;

an input electrode formed on the first surface portion of the first surface of the piezoelectric member;

a ground electrode formed on the first surface portion of the second surface of the piezoelectric member while being vertically symmetrical with the input electrode; and

an output electrode formed on the second portion of the piezoelectric member at an end of the second portion spaced away from the input electrode, the output electrode including a first electrode portion formed on the first surface of the piezoelectric member, a second electrode portion formed on the second surface of the piezoelectric member while being vertically symmetrical with the first electrode portion, and a third electrode portion formed on the side surface of the piezoelectric member spaced away from the input electrode, the third electrode portion serving to connect the first and second electrode portions.

In accordance with another aspect, the present invention provides a piezoelectric transformer comprising:

a piezoelectric member having two opposite rectangular major surfaces as first and second surfaces, and four side surfaces connecting the first and second surfaces, the piezoelectric member being longitudinally divided into three portions to have opposite end portions, and an intermediate portion arranged between the opposite end portions, thereby longitudinally dividing each of the first and second surfaces of the piezoelectric member into opposite end surface portions, and an intermediate surface portion;

an input electrode formed on the intermediate surface portion of the first surface of the piezoelectric member;

a ground electrode formed on the second surface of the piezoelectric member while being vertically symmetrical with the input electrode; and

a pair of output electrodes respectively formed on the opposite end portions of the piezoelectric member at opposite ends of the piezoelectric member, each of the output electrodes including a first electrode portion formed on the first surface of the piezoelectric member, a second electrode portion formed on the second surface of the piezoelectric member while being vertically symmetrical with the first electrode portion, and a third electrode portion formed on the side surface of the piezoelectric member arranged at the end of the piezoelectric member associated therewith, the third electrode portion serving to connect the first and second electrode portions.

Preferably, the first and second electrode portions of the output electrode have an electrode width of 0.5 mm or more.

In order to longitudinally polarize the piezoelectric transformer at an output section thereof, positive voltage is applied to the input and ground electrodes while negative voltage is applied to the first electrode portion of the output electrode.

The output electrode is connected to an external electrode at the center of the first electrode portion thereof.

In accordance with another aspect, the present invention provides a method for manufacturing a piezoelectric transformer as claimed in claim 1 or 2, comprising the steps of:

preparing a piezoelectric member having two opposite rectangular major surfaces as first and second surfaces, and four side surfaces connecting the first and second surfaces;

forming an input electrode and a first electrode portion of an output electrode on the first surface of the piezoelectric member so that the input electrode and the first electrode portion are spaced apart from each other;

forming a ground electrode and a second electrode portion of the output electrode on the second surface of the piezoelectric member while allowing the ground electrode and the second electrode portion to be vertically symmetrical with the input electrode and the first electrode portion, respectively; and

printing a third electrode portion of the output electrode on the side surface of the piezoelectric member spaced away from the input and ground electrodes so that the third electrode portion connects the first and second electrode portion, whereby the first through third electrode portions connected together form the output electrode.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view illustrating the basic configuration of a conventional Rozen type piezoelectric transformer, along with a waveform diagram showing the waveform of vibrations generated at the piezoelectric transformer;

FIG. 2 is a perspective view illustrating another conventional Rozen type piezoelectric transformer improved over the piezoelectric transformer of FIG. 1;

FIG. 3 is a perspective view illustrating a piezoelectric transformer according to an embodiment of the present invention;

FIG. 4 is a perspective view illustrating a piezoelectric transformer according to another embodiment of the present invention;

FIG. 5a is a schematic view illustrating a method for polarizing the conventional Rozen type piezoelectric transformer of FIG. 1;

FIG. 5b is a schematic view illustrating a method for polarizing the improved Rozen type piezoelectric transformer of FIG. 2;

FIG. 5c is a schematic view illustrating a method for polarizing the piezoelectric transformer of FIG. 3;

FIG. 6 is a graph depicting measurements of dispersion of piezoelectric characteristics for the improved Rozen type piezoelectric transformer of FIG. 2; and

FIG. 7 is a graph depicting measurements of dispersion of piezoelectric characteristics for the piezoelectric transformer of the present invention.

### DESCRIPTION OF THE PREFERRED EMBODIMENTS

Now, a piezoelectric transformer according to the present invention will be described with reference to the annexed drawings.

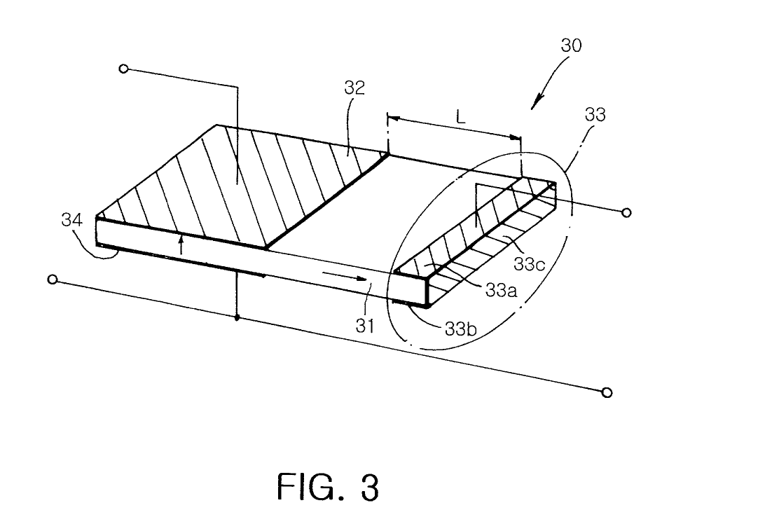

FIG. 3 is a perspective view illustrating a piezoelectric transformer according to an embodiment of the present invention.

Basically, the piezoelectric transformer, which is denoted by the reference numeral 30 in FIG. 3, includes a piezoelectric member 31 having two opposite rectangular major surfaces, that is, first and second surfaces, and four side surfaces, that is, third through sixth surfaces, connecting the first and second surfaces. The piezoelectric member 31 is longitudinally divided into two portions, that is, a first portion and a second portion. Accordingly, each of the first and second surfaces of the piezoelectric member 31 is longitudinally divided into two surface portions, that is, a first surface portion and a second surface portion. The piezoelectric transformer 30 also includes an input electrode 32 formed on the first surface portion of the first surface of the piezoelectric member 31. An output electrode 33 is formed on the second portion of the piezoelectric member 31 at the end of the second portion spaced away from the input electrode 32. The output electrode 33 includes a first electrode portion 33a formed on the first surface of the piezoelectric member 31, a second electrode portion 33b formed on the second surface of the piezoelectric member 31 while being vertically symmetrical with the first electrode portion 33a, and a third electrode portion 33c formed on the third surface of the piezoelectric member 31 spaced away from the input electrode 32 and adapted to connect the first and second electrode portions 33a and 33b. The piezoelectric transformer 30 further includes a ground electrode 34 formed on the first surface portion of the second surface of the piezoelectric member 31 while being vertically symmetrical with the input electrode 32.

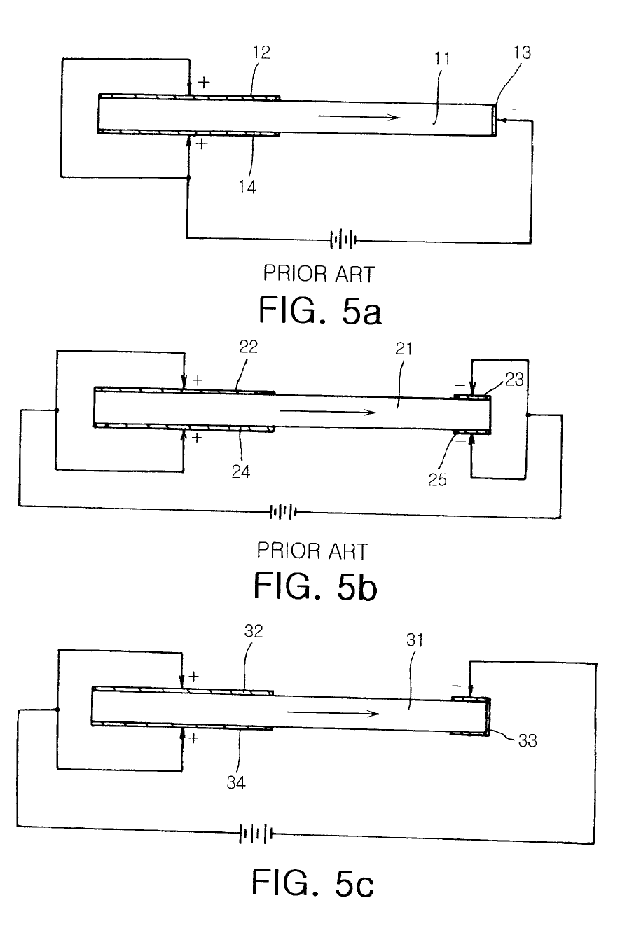

In the piezoelectric transformer 30 having the above described structure, its section formed with the input and ground electrodes 32 and 34 serves as a driving section, whereas its second section formed with the output electrode 33 serves as an electrical output generating section. As indicated by arrows in FIG. 3, the driving section is vertically polarized, whereas the electrical output generating section is longitudinally polarized. The polarization of the piezoelectric transformer 30 at its input stage is performed when negative voltage is applied to the input electrode 32 while positive voltage is applied to the ground voltage 34. That is, the driving section of the piezoelectric transformer is vertically polarized. On the other hand, the polarization of the piezoelectric transformer 30 at its output stage is performed when positive voltage is applied to both the input electrode 32 and the ground voltage 34 while negative voltage is applied to the first electrode portion 33a of the output electrode 33, as shown in FIG. 5c. That is, the electrical output generating section of the piezoelectric member 31 is longitudinally polarized. When negative voltage is applied to the first electrode portion 33a of the output electrode 33 formed on the first surface of the piezoelectric member 31, it is also supplied to the third electrode portion 33c arranged at the associated side surface of the piezoelectric member 31 because the third electrode portion 33c is connected to the first electrode portion 33a. As a result, superior dispersion of polarization characteristics is achieved. Since negative voltage can be coupled to the first surface of the piezoelectric member 31 formed with the input electrode 32, it is possible to easily achieve external electrical connection and polarization of the output electrode 33.

The first and second electrode portions 33a and 33b of the output electrode 33 should have an electrode width of 0.5 mm or more. This width is a minimum width enabling external electrical connection of the output electrode and coupling of the output electrode to a desired voltage source for a desired polarization.

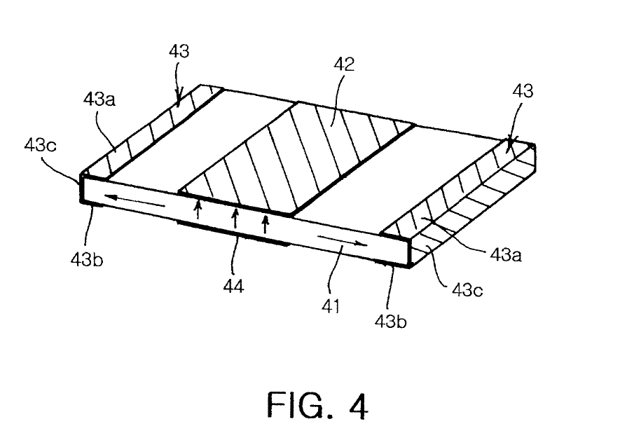

FIG. 4 is a perspective view illustrating a piezoelectric transformer according to another embodiment of the present invention.

Basically, the piezoelectric transformer, which is denoted by the reference numeral 40 in FIG. 4, includes a piezoelectric member 41 having two opposite rectangular major surfaces, that is, first and second surfaces, and four side surfaces, that is, third through sixth surfaces, connecting the first and second surfaces. The piezoelectric member 41 is longitudinally divided into three portions, that is, opposite end portions, and an intermediate portion arranged between the opposite end portions. Accordingly, each of the first and second surfaces of the piezoelectric member 41 is longitudinally divided into three surface portions, that is, opposite end surface portions, and an intermediate surface portion. The piezoelectric transformer 40 also includes an input electrode 42 formed on the intermediate surface portion of the first surface of the piezoelectric member 41, and a pair of output electrodes 43 respectively formed on the opposite end portions of the piezoelectric member 41 at opposite ends of the piezoelectric member 41. Each output electrode 43 includes a first electrode portion 43a formed on the first surface of the piezoelectric member 31, a second electrode portion 43b formed on the second surface of the piezoelectric member 31 while being vertically symmetrical with the first electrode portion 43a, and a third electrode portion 43c formed on the side surface of the piezoelectric member 41 arranged at the associated end of the piezoelectric member 41, that is, the third or fourth side surface, and adapted to connect the first and second electrode portions 33a and 33b. The piezoelectric transformer 40 further includes a ground electrode 44 formed on the intermediate surface portion of the second surface of the piezoelectric member 41 while being vertically symmetrical with the input electrode 42.

In the piezoelectric transformer 40 having the above described structure, its intermediate section formed with the input and ground electrodes 42 and 44 serves as a driving section, whereas its opposite end sections respectively formed with the output electrodes 43 as serve electrical output generating sections. The output electrodes 43 may be connected to the same load. Alternatively, the output electrodes 43 may be connected to different loads, respectively.

As indicated by arrows in FIG. 4, the driving section is vertically polarized, whereas the electrical output generating sections are longitudinally polarized.

Similarly to the above described embodiment of the present invention, the longitudinal polarization of the piezoelectric transformer 40 is performed when positive voltage is applied to both the input and ground electrodes 42 and 44 while negative voltage is applied to both the first electrode portions 43a of the output electrodes 43.

Thus, it is possible to easily achieve application of positive and negative voltages for a desired polarization. Also, superior dispersion of polarization characteristics is achieved because negative voltage is also applied to the third and fourth surfaces of the piezoelectric member 41 extending in a direction perpendicular to the polarization direction.

The first and second electrode portions 43a and 43b of each output electrode 43 should have an electrode width of 0.5 mm or more. This width is a minimum width enabling external electrical connection of each output electrode and coupling of the output electrode to a desired voltage source for a desired polarization.

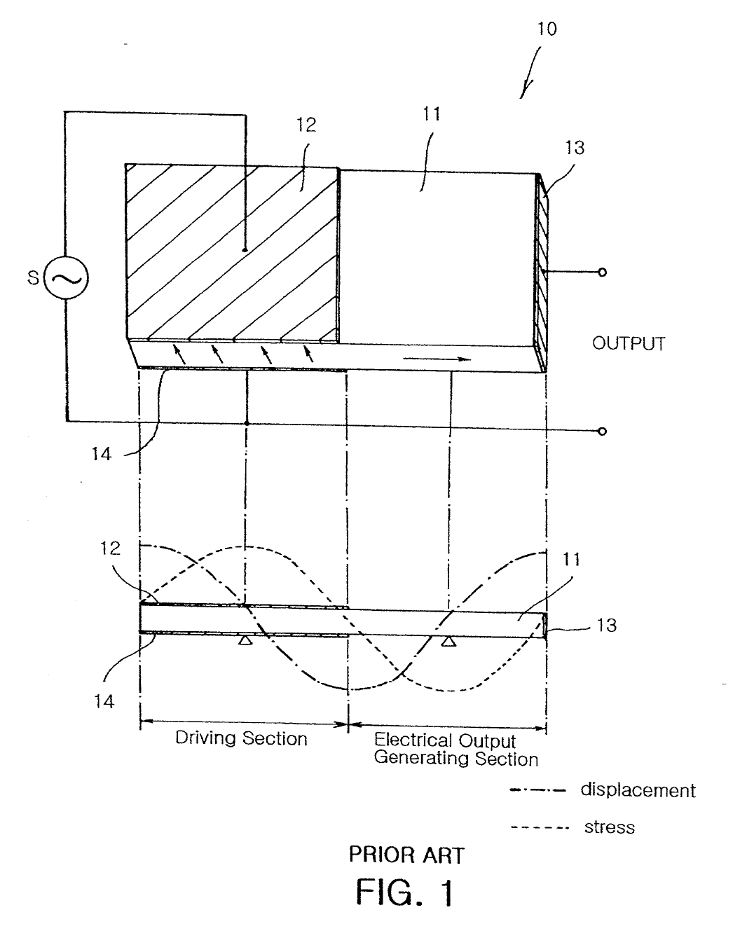

FIG. 5a illustrates a method for polarizing the conventional Rozen type piezoelectric transformer of FIG. 1. In accordance with this method, positive voltage is coupled to both the input and ground electrodes 12 and 14, whereas negative voltage is coupled to the output electrode 13, in order to apply voltage of a desired high level across the piezoelectric transformer. As the high-level voltage is applied across the piezoelectric transformer, the electrical output generating section of the piezoelectric transformer is longitudinally polarized. However, this method has a problem in that it is inconvenient to couple the output electrode 13 to the negative voltage source because the output electrode 13 is arranged at the narrow side surface of the piezoelectric member having a thin structure. Furthermore, the piezoelectric member is likely to be damaged.

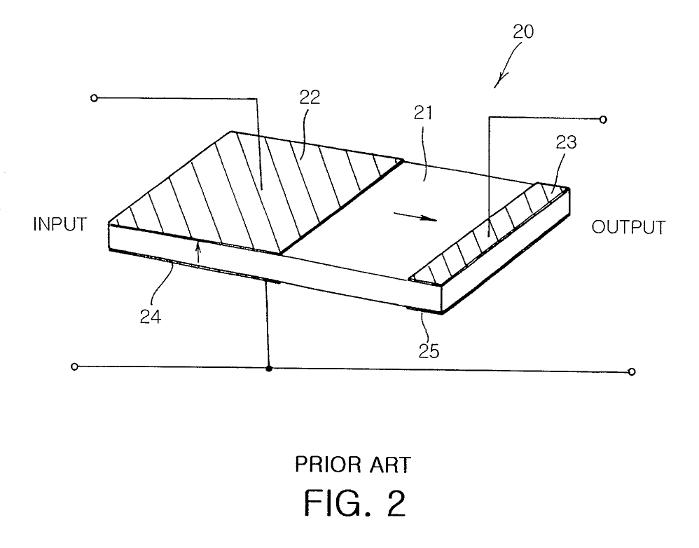

FIG. 5b illustrates a method for polarizing the conventional Rozen type piezoelectric transformer of FIG. 2 having an improved structure, compared to that of FIG. 1. In accordance with this method, positive voltage is coupled to both the input and ground electrodes 22 and 24, whereas negative voltage is coupled to both the output and ground electrodes 23 and 25, in order to longitudinally polarize the electrical output generating section of the piezoelectric transformer. In this case, although coupling of electrodes to associated voltage sources is complex, as compared to the Rozen type piezoelectric transformer of FIG. 1, it is possible to prevent the piezoelectric member from being damaged because the electrodes, which are coupled to the voltage sources, are formed on the first and second surfaces of the piezoelectric member having a width larger than that of the compared side surface. However, dispersion of polarization characteristics may occur because negative voltage is applied to the output electrode 23 extending in the same direction as the polarization direction. As a result, there may be a degradation in quality.

FIG. 5c illustrates a method for polarizing the piezoelectric transformer of FIG. 3 according to the present invention. In accordance with this method, positive voltage is coupled to both the input and ground electrodes 32 and 34, whereas negative voltage is coupled to the output electrode 33. In this case, coupling of the electrodes to associated voltage sources is not achieved at any side surfaces of the piezoelectric member 31, but achieved at the first and second surfaces of the piezoelectric member 31. In particular, the voltage source associated with the output electrode 33 is coupled to the first electrode portion 33a arranged on the first surface of the piezoelectric member 31 or the second electrode portion 33b arranged on the second surface of the piezoelectric member 31. Accordingly, it is possible to easily achieve a desired polarization. It is also possible to reduce dispersion of polarization characteristics, because the negative voltage applied to the first or second electrode portion 33a and 33b of the piezoelectric member 31 is supplied even to the third electrode portion 33c covering the associated side surface of the piezoelectric member 31. Similarly to the coupling to the associated voltage source, external electrical connection of the output electrode can be easily achieved, as compared to the improved Rozen type piezoelectric transformer of FIG. 5b, because it is made at the first electrode portion 33a arranged on the first surface of the piezoelectric member 31 or the second electrode portion 33b arranged on the second surface of the piezoelectric member 31. Thus, the piezoelectric transformer according to the present invention has both the advantages of the conventional Rozen type piezoelectric transformer of FIG. 1 and the advantages of the improved Rozen type piezoelectric transformer of FIG. 2.

The following Table 1 shows average piezoelectric characteristics obtained by testing the conventional Rozen type piezoelectric transformer of FIG. 1, the improved Rozen type piezoelectric transformer of FIG. 2, and the piezoelectric transformer of the present invention in terms of piezoelectric characteristics. Referring to Table 1, it can be seen that the piezoelectric transformer of the present invention exhibits reduced voltage loss, and an improved efficiency, as compared to the conventional piezoelectric transformers.

TABLE 1

| | Electrical-Mechanical | Piezoelectric |
|---|---|---|
| Piezoelectric | Coupling Factor | Quality Factor |
| Transformers | (K33) | (Qm) |
| Rozen Type | 0.419 | 446.166 |
| (FIG. 1) | | |
| Improved Rozen Type | 0.449 | 407.896 |
| (FIG. 2) | | |
| Present Invention | 0.451 | 474.647 |
| (FIG. 3) | | |

In Table 1, “K33” is an electrical-mechanical coupling factor. When the value of this factor “K33” increases, an increased efficiency is obtained. “Qm” is a piezoelectric quality factor. When the value of this factor “Qm” increases, the voltage loss of the piezoelectric transformer is reduced.

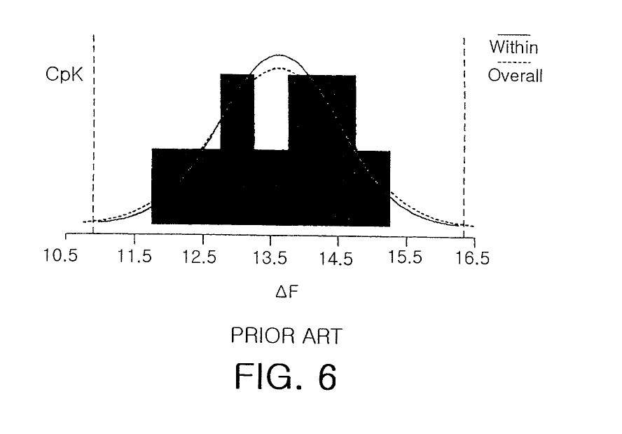

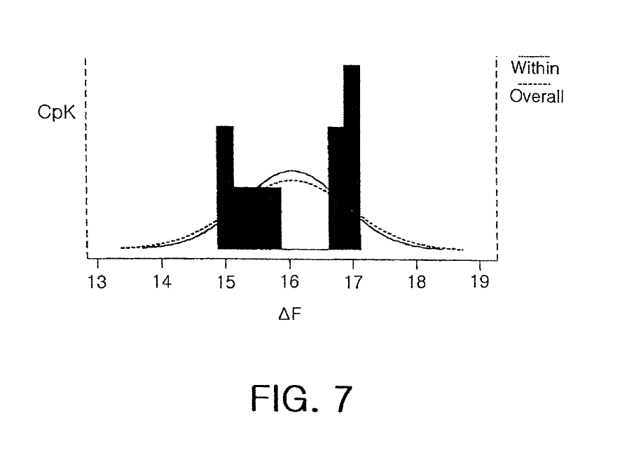

FIGS. 6 and 7 are graphs respectively depicting measurements of dispersion of piezoelectric characteristics for the improved Rozen type piezoelectric transformer and the piezoelectric transformer of the present invention. In FIGS. 6 and 7, “ΔF” is piezoelectric characteristics corresponding to the difference between the resonant and anti-resonant frequencies Fr and Fa of the piezoelectric transformer (ΔF=Fa−Fr). The value of this factor “ΔF” is desired to be high while being uniformly distributed. Referring to FIGS. 6 and 7, it can be seen that the piezoelectric transformer of the present invention exhibits piezoelectric characteristics having a high average value while being reduced in dispersion. Thus, the present invention can achieve the quality of piezoelectric characteristics while reducing dispersion of piezoelectric characteristics.

As apparent from the above description, the present invention provides a piezoelectric transformer which can exhibit improved dispersion of characteristics, and maximum piezoelectric characteristics while easily achieving external electrical connection and polarization of electrodes. In accordance with the present invention, it is also possible to adjust the output impedance of the piezoelectric transformer to be matched with a load coupled to the output stage of the piezoelectric transformer, by adjusting the electrode width at the output stage. Where it is desired to obtain a maximum efficiency by matching the output impedance of the piezoelectric transformer with a load, for example, a lamp, this can be easily achieved by simply adjusting the length of the external electrode connection terminal at the output stage without varying the size of the piezoelectric transformer, thereby adjusting the capacitance at the output stage.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A piezoelectric transformer comprising:
a piezoelectric member having two opposite rectangular major surfaces as first and second surfaces, and four side surfaces connecting the first and second surfaces, the piezoelectric member being longitudinally divided into two portions to have a first portion and a second portion, thereby longitudinally dividing each of the first and second surfaces into a first surface portion and a second surface portion;
an input electrode formed on the first surface portion of the first surface of the piezoelectric member;
a ground electrode formed on the first surface portion of the second surface of the piezoelectric member while being vertically symmetrical with the input electrode; and
an output electrode formed on the second portion of the piezoelectric member at an end of the second portion spaced away from the input electrode, the output electrode including a first electrode portion formed on the first surface of the piezoelectric member, a second electrode portion formed on the second surface of the piezoelectric member while being vertically symmetrical with the first electrode portion, and a third electrode portion formed on the side surface of the piezoelectric member spaced away from the input electrode, the third electrode portion serving to connect the first and second electrode portions.

2. A piezoelectric transformer comprising:
a piezoelectric member having two opposite rectangular major surfaces as first and second surfaces, and four side surfaces connecting the first and second surfaces, the piezoelectric member being longitudinally divided into three portions to have opposite end portions, and an intermediate portion arranged between the opposite end portions, thereby longitudinally dividing each of the first and second surfaces of the piezoelectric member into opposite end surface portions, and an intermediate surface portion;
an input electrode formed on the intermediate surface portion of the first surface of the piezoelectric member;
a ground electrode formed on the second surface of the piezoelectric member while being vertically symmetrical with the input electrode; and
a pair of output electrodes respectively formed on the opposite end portions of the piezoelectric member at opposite ends of the piezoelectric member, each of the output electrodes including a first electrode portion formed on the first surface of the piezoelectric member, a second electrode portion formed on the second surface of the piezoelectric member while being vertically symmetrical with the first electrode portion, and a third electrode portion formed on the side surface of the piezoelectric member arranged at the end of the piezoelectric member associated therewith, the third electrode portion serving to connect the first and second electrode portions.

3. The piezoelectric transformer according to claim 1 or 2, wherein the first and second electrode portions of the output electrode has an electrode width of 0.5 mm or more.

4. The piezoelectric transformer according to claim 1 or 2, wherein positive voltage is applied to the input and ground electrodes, whereas negative voltage is applied to the first electrode portion of the output electrode, whereby the piezoelectric transformer is longitudinally polarized at an output section thereof.

5. The piezoelectric transformer according to claim 1 or 2, wherein the output electrode is connected to an external electrode at the center of the first electrode portion thereof.

6. The piezoelectric transformer according to claim 1 or 2, wherein each of the first and second electrode portions of the output electrode is adjusted in width to adjust output impedance exhibited at an output stage of the piezoelectric transformer when the output stage is coupled to a load.

7. The piezoelectric transformer according to claim 1 or 2, wherein the input, ground, and output electrodes are formed in accordance with a screen printing method.

8. A method for manufacturing a piezoelectric transformer as claimed in claim 1 or 2, comprising the steps of:
preparing a piezoelectric member having two opposite rectangular major surfaces as first and second surfaces, and four side surfaces connecting the first and second surfaces;
forming an input electrode and a first electrode portion of an output electrode on the first surface of the piezoelectric member so that the input electrode and the first electrode portion are spaced apart from each other;
forming a ground electrode and a second electrode portion of the output electrode on the second surface of the piezoelectric member while allowing the ground electrode and the second electrode portion to be vertically symmetrical with the input electrode and the first electrode portion, respectively; and
printing a third electrode portion of the output electrode on the side surface of the piezoelectric member spaced away from the input and ground electrodes so that the third electrode portion connects the first and second electrode portion, whereby the first through third electrode portions connected together form the output electrode.
